(19) United States
(12) Patent Application Publication
(10) Pub. No.: US 2022/0393665 A1
(43) Pub. Date: Dec. 8, 2022

(54) ACOUSTIC WAVE DEVICE

(71) Applicant: KYOCERA Corporation, Kyoto-shi, Kyoto (JP)

(72) Inventor: Soichiro NOZOE, Soraku-gun (JP)

(73) Assignee: KYOCERA Corporation, Kyoto-shi, Kyoto (JP)

(21) Appl. No.: 17/768,310

(22) PCT Filed: Oct. 16, 2020
(86) PCT No.: PCT/JP2020/039034

§ 371 Date: Apr. 12, 2022

(30) Foreign Application Priority Data
Oct. 24, 2019 (JP) 2019-193589

(51) Int. Cl. H03H 9/25; H03H 9/145; H03H 9/64; H03H 9/02

(52) U.S. Cl. CPC H03H 9/25; H03H 9/145; H03H 9/6483; H03H 9/02543

(57) ABSTRACT

Provided is an acoustic wave device that uses a plate wave. The acoustic wave device includes a piezoelectric film and a first resonator and a second resonator each including an IDT electrode located on an upper surface of the piezoelectric film. The thickness of the piezoelectric film is smaller than twice the period of the electrode fingers of the IDT electrodes. The duty of the electrode fingers of the first resonator and the duty of the electrode fingers of the second resonator are different from each other.

### FIELD OF INVENTION

The present disclosure relates to an acoustic wave device used in resonators, band filters, and so forth, and more specifically, relates to an acoustic wave device that uses a plate wave.

### TECHNICAL BACKGROUND

Heretofore, acoustic wave devices that use various types of acoustic waves such as a Rayleigh wave and a shear horizontal (SH) wave have been proposed. PTL 1 discloses an acoustic wave device that uses a plate wave.

The acoustic wave device disclosed in PTL 1 includes a silicon substrate, an acoustic reflector stacked on the silicon substrate, a piezoelectric film formed on the acoustic reflector, and an interdigital transducer (IDT) electrode formed on the piezoelectric film. Furthermore the acoustic reflector is formed by alternately stacking high and low acoustic wave impedance films.

### CITATION LIST

### Patent Literature

PTL 1: Japanese Unexamined Patent Application Publication (Translation of PCT Application) No. 2008-530874

### SUMMARY

An acoustic wave device according to an embodiment of the present disclosure uses a plate wave and includes a piezoelectric film and a first resonator and a second resonator each including an IDT electrode located on an upper surface of the piezoelectric film. A thickness of the piezoelectric film is smaller than twice a period of electrode fingers of the IDT electrode of each of the first resonator and the second resonator. A duty of the electrode fingers of the IDT electrode of the first resonator and a duty of the electrode fingers of the IDT electrode of the second resonator are different from each other.

An acoustic wave device according to an embodiment of the present disclosure includes: a piezoelectric film composed of 106° Y rotation X propagation lithium tantalate single crystal, 114° Y rotation X propagation lithium tantalate single crystal, or 105° Y rotation X propagation lithium niobate single crystal; and a first resonator and a second resonator each including an IDT electrode located on an upper surface of the piezoelectric film. A thickness of the piezoelectric film is smaller than twice a period of electrode fingers of the IDT electrode of each of the first resonator and the second resonator. The duty of the electrode fingers of the first resonator and the duty of the electrode fingers of the second resonator are different from each other.

An acoustic wave device according to an embodiment of the present disclosure includes: a support substrate; a multilayer film located on the support substrate; a piezoelectric film located on the multilayer film; and a first resonator and a second resonator each including an IDT electrode located on an upper surface of the piezoelectric film. A thickness of the piezoelectric film is smaller than a period of electrode fingers of the IDT electrode of each of the first resonator and the second resonator. The acoustic wave device uses a plate wave. The multilayer film includes a first layer and a second layer having a higher acoustic impedance than the first layer, and a duty of the first resonator and a duty of the second resonator lie in a range from 0.29 to 0.31.

### BRIEF DESCRIPTION OF DRAWINGS

FIG. 1A is a sectional view of an acoustic wave device according to an embodiment of the present disclosure and FIG. 1B is a schematic plan view illustrating a main part of FIG. 1A.

FIG. 2 is a circuit diagram illustrating the acoustic wave device according to the embodiment of the present disclosure.

FIG. 3 illustrates charts depicting frequency characteristics of an acoustic wave device of the related art.

FIG. 4 is a chart illustrating correlations between piezoelectric film thickness and spurious frequency in the acoustic wave device of the related art.

FIG. 5 is a chart illustrating correlations between piezoelectric film thickness and spurious frequency in the acoustic wave device according to the embodiment of the present disclosure.

FIG. 6A is a chart illustrating correlations between resonant frequency and duty for a resonator on a low-frequency side and FIG. 6B is a chart illustrating the correlations between resonant frequency and duty for a resonator on a high-frequency side.

FIG. 7 is a table illustrating design parameters of resonators that satisfy FIG. 6B.

FIG. 8 is a chart illustrating the frequency characteristics of the resonators illustrated in FIG. 7.

FIGS. 9A and 9B are charts illustrating correlations between piezoelectric film thickness, spurious frequency, and spurious intensity in resonators of the acoustic wave device according to the embodiment of the present disclosure.

FIG. 10 is a sectional view illustrating an acoustic wave device according to another embodiment of the present disclosure.

FIG. 11 is a chart illustrating correlations between piezoelectric film thickness, spurious frequency, and spurious intensity in a resonator of the acoustic wave device illustrated in FIG. 10.

FIG. 12A is a chart illustrating correlations between piezoelectric film thickness and spurious frequency in an acoustic wave device of the related art and FIG. 12B is a chart illustrating correlations between piezoelectric film thickness and spurious frequency in an acoustic wave device according to another embodiment of the present disclosure.

FIGS. 13A and 13B are diagrams corresponding to FIGS. 6A and 6B for resonators in an acoustic wave device according to another embodiment of the present disclosure.

FIGS. 14A and 14B are diagrams corresponding to FIGS. 7 and 8 for an acoustic wave device according to another embodiment of the present disclosure.

### DETAILED DESCRIPTION

Hereafter, specific embodiments of the present disclosure will be described while referring to the drawings.

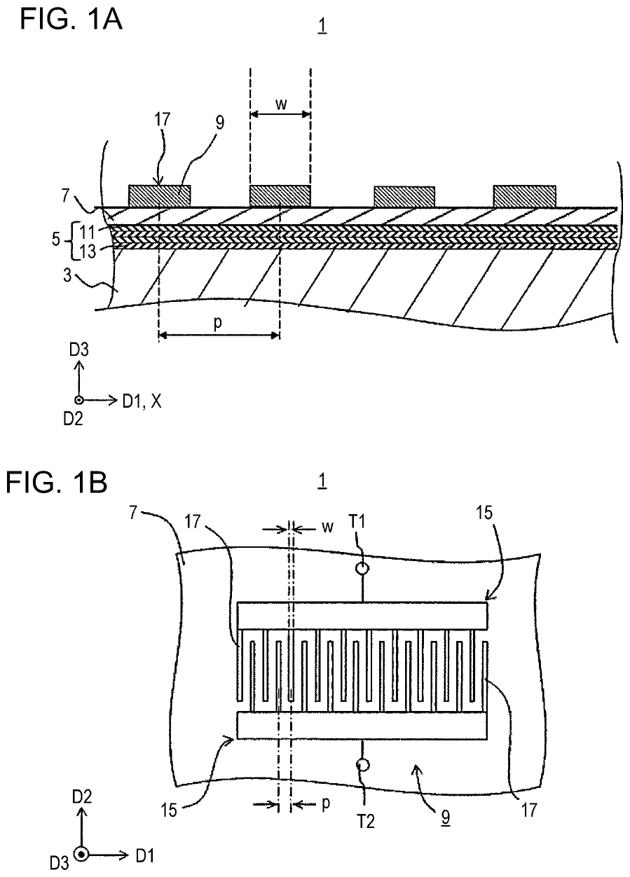

FIG. 1A is a sectional view of an acoustic wave device according to an embodiment of the present disclosure and FIG. 1B is a schematic plan view illustrating a main part of FIG. 1A. Mutually perpendicular axes D1, D2, and D3 are defined in the drawings with a positive thickness direction being a positive direction of the axis D3.

An acoustic wave device 1 is an acoustic wave device that uses plate waves. In this example, the acoustic wave device 1 includes a support substrate 3, a multilayer film 5 located on the support substrate 3, a piezoelectric film 7 located on the multilayer film 5, and an IDT electrode 9 located on the piezoelectric film 7. The acoustic wave device 1 includes a first resonator and a second resonator, which each include the IDT electrode 9. As described later, the thickness of the piezoelectric film 7 is designed and the IDT electrodes 9 are designed so that the first resonator and the second resonator each have a desired resonant frequency and so that the first resonator and second resonator suppress spurious.

The material constituting the support substrate 3 is not particularly limited so long as the support substrate 3 is able to support the multilayer film 5 and the piezoelectric film 7 located above the support substrate 3. For example, a Si substrate, a ceramic substrate, a glass substrate, an organic substrate, or a sapphire substrate can be used. For example, a piezoelectric crystal substrate composed of quartz (SiO₂), lithium niobate (LiNbO₃: hereinafter referred to as LN), or lithium tantalate (LiTaO₃: hereinafter referred to as LT) can be used. The support substrate 3 may be made of a single material or may be made of two or more materials such as two or more layers of different materials stacked on top of each other.

The thickness of the support substrate 3 is not particularly limited so long as the support substrate 3 is able to support structures located above the support substrate 3, and may be from 50 μm to 250 μm, for example.

The multilayer film 5 is located on the support substrate 3. The support substrate 3 and the multilayer film 5 may be directly bonded to each other or may be indirectly bonded to each other with, for example, a bonding layer, a planarization layer, and/or an adhesive layer, which are not illustrated, interposed therebetween.

The multilayer film 5 is formed by alternately stacking a first layer 11 and a second layer 13. The materials of these layers may be selected as appropriate so that, for example, the acoustic impedance of the second layers 13 is higher than the acoustic impedance of the first layers 11. As a result, for example, the reflectivity at the boundary between the first layer 11 and the second layer 13 is comparatively high for acoustic waves. This results in reduced leakage of acoustic waves propagating through the piezoelectric film 7. Specifically, for example, the material of the first layers 11 may be silicon dioxide (SiO₂). In this case, the material of the second layers 13 may be, for example, tantalum pentoxide (Ta₂O₅), hafnium oxide (HfO₂), zirconium dioxide (ZrO₂), titanium oxide (TiO₂), or magnesium oxide (MgO).

The number of layers stacked in the multilayer film 5 may be set as appropriate. For example, the total number of stacked layers of the first layers 11 and the second layers 13 in the multilayer film 5 may be from 3 to 12 layers. However, the multilayer film 5 may be formed of a total of two layers including one first layer 11 and one second layer 13. In addition, the total number of stacked layers making up the multilayer film 5 may be an even number or an odd number. The layer in contact with the piezoelectric film 7 is, for example, a first layer 11. The layer in contact with the substrate 3 may be a first layer 11 or a second layer 13.

The thicknesses of the first layers 11 and the second layers 13 may be determined so as to increase the reflectivity for plate waves, for example. In the following description, values such as 0.20 μm and 0.17 μm will be given as specific examples of the thicknesses of the first layers 11 and the second layers 13. The thicknesses of the first layers 11 and the second layers 13 may be set so as to lie within a range of ±0.01 μm around the example values.

For example, LT, LN, zinc oxide (ZnO), aluminum nitride (AlN), or quartz may be used as the material of the piezoelectric film 7. Plate waves can be effectively excited using these materials.

Specifically, for example, when the material of the piezoelectric film 7 is LT, the piezoelectric film 7 may be represented using Euler angles (φ, θ, ψ) as (0°±20°, −5° to 65°, 0°±10°). From another viewpoint, the piezoelectric film 7 may be a rotated Y-cut X propagation film, and the Y axis may be inclined at an angle from 85° to 155° with respect to a line normal to the piezoelectric film 7 (D3 axis). In addition, a piezoelectric film 7 represented using Euler angles equivalent to those given above may also be used. For example, Euler angles of (180°±10°, −65° to 5°, 0°±10°) and Euler angles obtained by adding or subtracting 120° to or from φ may be given as Euler angles equivalent to those given above.

In addition, for example, when the material of the piezoelectric film 7 is LN, the piezoelectric film 7 may be represented using Euler angles (φ, θ, ψ) of (0°, 0°±20°, A°). Here, A° has a value from 0° to 360°. In other words, A° may be any angle.

The thickness of the piezoelectric film 7 is less than 2p with respect to a pitch p of electrode fingers 17 of the IDT electrode 9 described later (for example, the smallest pitch when two or more resonators (IDT electrodes) are provided). Since the piezoelectric film 7 of the acoustic wave device 1 is very thin, plate waves are efficiently excited when a voltage is applied to the IDT electrode 9. Furthermore, plate waves leaking from the side near the multilayer film 5 are reflected back into the piezoelectric film 7, and therefore loss of the generated plate waves can be reduced and the energy intensity of the plate waves propagating inside the piezoelectric film 7 can be increased.

Furthermore, the thickness of the piezoelectric film 7 may be less than 1p. In this case, plate waves can be efficiently excited with a pitch p that is of a sufficient size to allow the electrode fingers 17 of the IDT electrodes 9 to be stably manufactured. Furthermore, the thickness of the piezoelectric film 7 may be less than 0.6p. In this case, spurious, which is described later, can be reduced. For example, A1 mode Lamb waves can be given as an example of plate waves.

Plate waves are classified into Lamb waves (main component is in acoustic wave propagation direction and piezoelectric film thickness direction) and SH waves (main component is an SH component) in accordance with their displacement components. Lamb waves are further classified into a symmetrical mode (S mode) and an anti-symmetrical mode (A mode). When the waves are folded back on themselves along a line halfway through the thickness of the piezoelectric film, waves having overlapping displacements are considered to be waves of a symmetrical mode and waves having displacements in opposite directions are considered to be waves of an anti-symmetrical mode. Here, A1 mode Lamb waves are first order anti-symmetrical mode Lamb waves.

The IDT electrode 9 is, for example, formed of a metal. The metal may be any suitable metal and, for example, may be aluminum (Al) or an alloy having Al as a main component (Al alloy). The Al alloy is, for example, an aluminum-copper (Cu) alloy. The IDT electrode 9 may be formed of a plurality of metal layers. For example, a relatively thin layer composed of titanium (Ti) may be provided between the Al or Al alloy and the piezoelectric film 7 in order to strengthen the bond therebetween. The thickness of the IDT electrode 9 may be set as appropriate. For example, the thickness of the IDT electrode 9 may be set in a range from 0.04p to 0.2p.

As illustrated in FIG. 1B, the IDT electrode 9 includes a pair of comb-shaped electrodes 15. The comb-shaped electrodes 15 each have a plurality of electrode fingers 17 corresponding to the teeth of the comb shape and the electrode fingers 17 are disposed so as to interlace with (cross) each other.

The electrode fingers 17 are arrayed at a pitch p in a repetitive array direction (propagation direction of plate waves). The pitch p represents the interval between the centers of the widths of the electrode fingers 17 in the repetitive array direction (propagation direction of plate waves). w represents the width of the electrode fingers 17 in the repetitive array direction and w/p represents the duty of the IDT electrode 9.

The pitch (period) p of the plurality of electrode fingers 17 (distance between the centers of two adjacent electrode fingers 17) is basically constant within the IDT electrode 9. Note that the IDT electrode 9 may have some parts that are different in terms of the pitch p. Examples of such different parts include, for example, small pitch parts where the pitch p is smaller than that of the majority (for example, 80% or more) of the electrode fingers 17, large pitch parts where the pitch p is larger than that of the majority of the electrode fingers 17, and withdrawal areas where a small number of electrode fingers 17 have been substantially withdrawn.

Hereafter, when the pitch p is referred to, unless otherwise specified, the pitch p refers to the pitch of the parts (majority of the plurality of electrode fingers 17) excluding the different parts described above. In addition, in the case where the pitch changes even in the majority of the plurality of electrode fingers 17 excluding the different parts, the average value of the pitch of the majority of the plurality of electrode fingers 17 may be used as the value of the pitch p. The same applies to the duty of the IDT electrode 9.

The IDT electrode 9 may include dummy electrodes and so forth. Furthermore, the acoustic wave device 1 may be provided with an insulating film that covers an upper part of the IDT electrode 9. The insulating film may be composed of a single material or may be a multilayer body including a plurality of layers of different materials. For example, SiO₂, Si₃N₄, or Ta₂O₅ may be used as the material of the insulating film.

The pitch p and duty of the IDT electrode 9 will be described later. In addition, reflector electrodes may be provided at both sides of the IDT electrode 9 in the direction in which the electrode fingers 17 are arrayed.

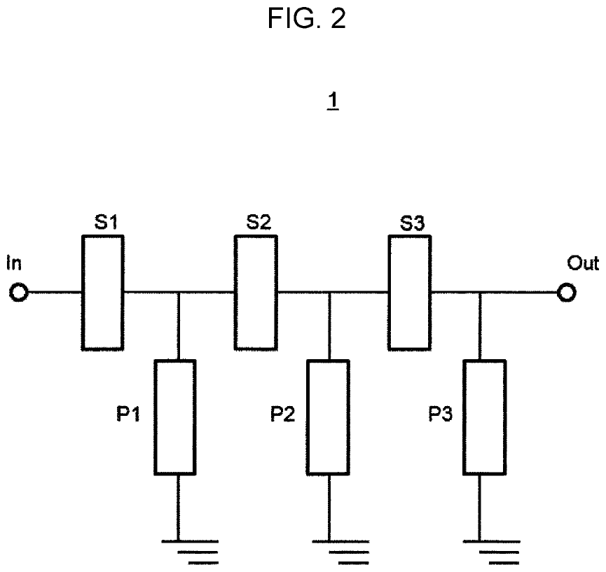

The IDT electrode 9 functions as a one-port resonator having radio-frequency signal input/output terminals T1 and T2. A band pass filter can be formed by connecting this resonator in a ladder configuration as illustrated in FIG. 2. FIG. 2 is a diagram illustrating the circuit configuration of the acoustic wave device 1.

In FIG. 2, the acoustic wave device 1 is formed of a plurality of series resonators S (S1 to S3) and a plurality of parallel resonators P (P1 to P3) connected in a ladder configuration between terminals In and Out. The individual resonators S and P are each formed of the IDT electrode 9 illustrated in FIG. 1B. Note that the shape of the IDT electrode 9 is illustrated in a simplified manner in FIG. 2.

The resonant frequencies of the series resonators S and the parallel resonators P need to be made different from each other in order for the acoustic wave device 1 to function as a band pass filter. A resonant frequency f has a value obtained by dividing an acoustic velocity V by a wavelength λ (f=V/λ). Here, the wavelength λ is expressed as 2p. From this, in an acoustic wave device of the related art, since the acoustic velocity V is constant, the resonant frequencies can be adjusted in a proportional manner by changing the pitches p of the IDT electrodes.

However, since the acoustic wave device 1 according to this embodiment uses plate waves, it may be difficult to adjust the frequencies by only adjusting the pitches p of the IDT electrodes 9. This is because the acoustic velocity of plate waves increases as the thickness of the piezoelectric film 7 decreases. In more detail, when the pitch p is increased in order to reduce the resonant frequency f, the wavelength λ also increases. On the other hand, the relative thickness of the piezoelectric film 7 with respect to λ decreases and therefore the acoustic velocity V increases. Applying this relationship to the equation f=V/λ, even if λ is increased in order to lower the frequency f, the acoustic velocity V will also increase and the change in the resonant frequency f will decrease. Thus, it is difficult to adjust the frequency f to a desired value. This presents an issue specific to a case where resonators having different resonant frequencies are provided on a piezoelectric film 7 having a uniform thickness.

Accordingly, in the acoustic wave device 1 according to this embodiment, the resonant frequencies of the series resonators S and the parallel resonators P are adjusted to desired values by also making the duties of the IDT electrodes 9 different in the series resonators S and the parallel resonators P in addition to making the pitches p of the IDT electrodes 9 different in the series resonators S and the parallel resonators P. The resonant frequency f can also be changed by changing the duty, and since the correlation between changes in duty and the acoustic velocity V is low, the resonant frequency f can be effectively changed.

Since the resonant frequency of the series resonators S (first resonator) is generally higher than the resonant frequency of the parallel resonators P (second resonator), desired resonant frequencies can be obtained by making a pitch p1 of the series resonators S smaller than a pitch p2 of the parallel resonators P and by making the duty of the series resonators S smaller than the duty of the parallel resonators P.

The acoustic wave device 1 of the above-described embodiment was manufactured with the following specifications.

Piezoelectric Film 7: Material LT, Cut Angle 114° Y Cut X Propagation

Multilayer Film 5: Number of Stacked Layers 8

First Layers 11: Material SiO₂, Thickness 0.2 μm, Number of Layers 4

Second Layers 13: Material HfO₂, Thickness 0.17 μm, Number of Layers 4

IDT Electrode 9: Material Al, Thickness

Series Resonators S: Pitch p1 1.0265 μm, Duty 0.3

Parallel Resonators P: Pitch p2 1.2607 μm, Duty 0.55

Support Substrate 3: Material Si, Thickness 200 μm

Furthermore, for comparison, an acoustic wave device having the same configuration except for the series resonators S and the parallel resonators P having the same duty was prepared as Comparative Example 1. The pitches p of the series resonators S and the parallel resonators P in Comparative Example 1 are values that allow a desired frequency difference to be obtained assuming that the acoustic velocity V is constant.

In this case, in the acoustic wave device 1, a resonant frequency f1 of the series resonators S was 5439 MHz and a resonant frequency f2 of the parallel resonators P was 5052 MHz. In contrast, in Comparative Example 1, the resonant frequency of the series resonators was 5439 MHz and the resonant frequency of the parallel resonators was 5190 MHz. When values of Δf, which is the difference between the resonant frequency and the anti-resonant frequency, were compared, Δf was 387 MHz for the acoustic wave device 1, whereas Δf was 249 MHz for Comparative Example 1, and it was thus confirmed that a sufficient change in frequency was not obtained in Comparative Example 1.

In the case where a pitch difference is created between the two resonators that is greater than the pitch difference at which the desired frequency difference is obtained assuming a constant acoustic velocity V, additionally, a difference in duty may also be created between the two resonators in the direction in which the frequency difference may increase. In other words, the duties may be made different in addition to changing the pitches more than a change in frequency. In other words, f1/f2<p2/p1 may set. In this case, it is even easier to realize the desired frequency difference. Specifically, f1/f2=p2/p1 when the acoustic velocity V is constant. In the above example, f1/f2 is 1.07, giving a change in frequency of 7%, whereas p2/p1 is 1.228, giving a change in pitch of around 23%.

Such adjustment of pitch and duty is particularly important when the band of the filter to be realized is wide. Specifically, such adjustment becomes more important when the fractional bandwidth is greater than or equal to 4%. As is widely known, the fractional bandwidth (or band width ratio) is a ratio obtained by dividing the bandwidth (passband) by the center frequency (the frequency at the center of the bandwidth). For example, a bandwidth of −3 dB can be given as the bandwidth.

### Relationship between Thickness of Piezoelectric Film 7 and Pitch of IDT Electrode 9

A large number of spurious signals are generated in a resonator using plate waves. Such spurious signals may be reduced between the resonant and anti-resonant frequencies by optimizing the cut angle and the thickness of the piezoelectric film 7, the pitch p and/or thickness of the IDT electrode 9, and so on. However, as described above, it is necessary to use resonators having different resonant frequencies in combination with each other in order to form the passband of the filter. Here, if an optimal configuration for reducing these spurious signals is tailored to one particular resonator, this configuration may deviate from the optimal configuration for another resonator, thereby resulting in a larger spurious effect for the acoustic wave device 1 as a whole.

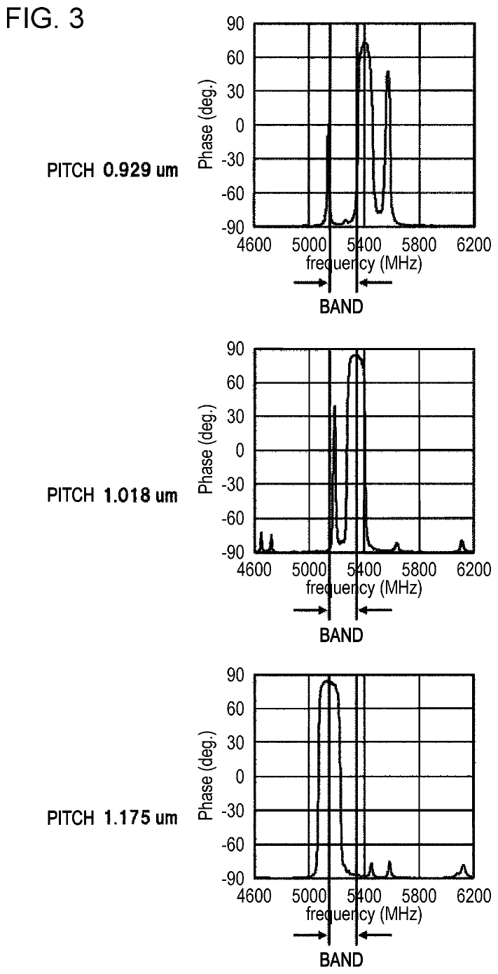

FIG. 3 illustrates resonator characteristics obtained when the resonant frequency was varied using only the pitch. Specifically, the pitches were 0.929 μm, 1.018 μm, and 1.175 μm. When the bandwidth to be realized is narrow, the filter can be realized using resonators having at least two different resonant frequencies, whereas when the bandwidth is wide, a plurality of resonators having a plurality of resonant frequencies (in this example three) are required, as illustrated in FIG. 3.

In FIG. 3, the horizontal axis represents frequency and the vertical axis represents phase of impedance. The location where the phase rises (boundary of low-frequency side of phase peak) roughly corresponds to the resonant frequency. The location where the phase falls (boundary on high-frequency side of phase peak) roughly corresponds to the anti-resonant frequency. The bandwidth in the case where a bandpass filter is formed using this resonator is also illustrated in the figure. As is clear from FIG. 3, it can be confirmed that spurious is also generated in the passband.

Here, the frequencies at which spurious of a resonator were generated were obtained by simulation while varying the thickness of the piezoelectric film 7. Here and in the following, the simulation was performed using a finite element method (FEM). FEM has little dependency on software, but for example, ANSYS Mecanical Ver 19.0 may be used. The basic model used in the simulation is as follows.

Support Substrate 3: Si Substrate

Multilayer Film 5: 8 Layers

First Layers 11: Material SiO₂, Thickness 0.2 μm, Number of Layers 4

Second Layers 13: Material HfO₂, Thickness 0.17 μm, Number of Layers 4

Piezoelectric Film 7: Material 114° Y Rotation X Propagation LT substrate

IDT Electrode 9: Material Al, Duty 0.5, Thickness 0.13 μm

The pitch p is adjusted under the conditions described above to realize the desired resonant frequency.

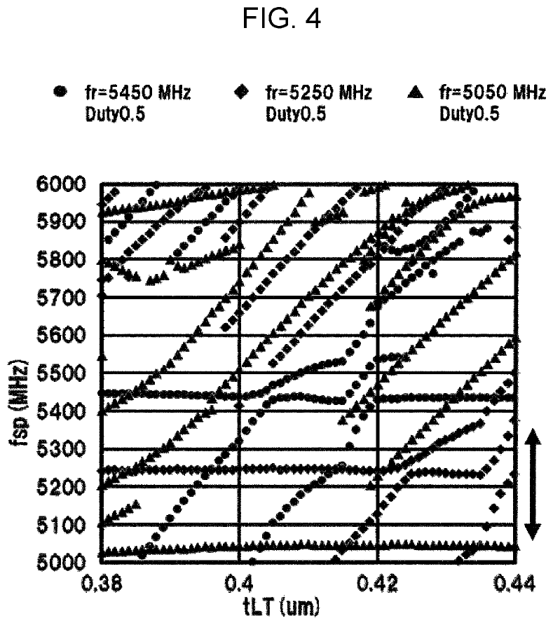

FIG. 4 illustrates the correlations between the thickness of the piezoelectric film 7 and the frequency of spurious for resonators realizing three resonant frequencies (5050 MHz, 5250 MHz, and 5450 MHz). The resonant frequencies are realizing by only changing the pitch p. For reference, the passband is illustrated in FIG. 4 using a double-headed arrow at the right side of the figure for a filter realized using the three resonant frequencies illustrated in FIG. 3. The pass band is specifically from 5.05 GHz to 5.35 GHz.

In FIG. 4, the horizontal axis represents thickness tLT of the piezoelectric film (units: μm) and the vertical axis represents frequency fsp of spurious (units: MHz). For each thickness, points are plotted at the frequencies at which the extreme values of the absolute impedance occur, and the frequencies of the resonance points (resonant frequencies) are plotted as well as the frequencies of spurious. Therefore, pluralities of plotted points roughly parallel to the horizontal axis in the vicinities of the resonant frequencies described above indicate the resonant frequencies. The remaining plotted points (pluralities of plotted points roughly aligned in directions inclined relative to the horizontal axis) indicate the frequencies of spurious. As illustrated in FIG. 4, it can be confirmed that spurious is frequently generated, including in the vicinities of the resonant frequencies, for all the values to which the thickness of the piezoelectric film is set.

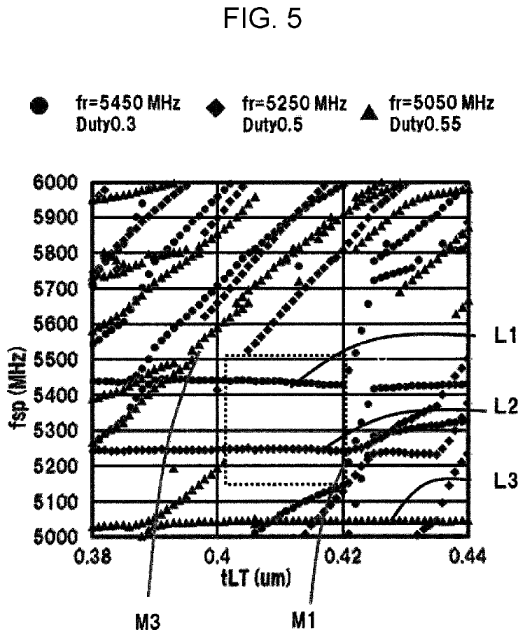

In contrast, the acoustic wave device 1 is able to reduce the effect of spurious. The results are illustrated in FIG. 5. FIG. 5 illustrates results obtained by adjusting the duty from 0.3 to 0.55 from the results in FIG. 4 in order to minimize the spurious. Specifically, the duty of a resonator R1, which realizes a resonant frequency of 5450 MHz, was set to 0.3, the duty of a resonator R2, which realizes a resonant frequency of 5250 MHz, was set to 0.3, and the duty of a resonator R3, which realizes a resonant frequency of 5050 MHz, was set to 0.55, and the frequencies of spurious generated by the resonators R1 to R3 were plotted.

In FIG. 5, there is a region where no spurious overlaps L1 to L3 indicating the resonant frequencies of the resonators R1 to R3 (hereinafter referred to as a spurious-free region). Specifically, a spurious-free region enclosed by a dotted line can be confirmed between one spurious mode M3 of the resonator R3 (indicated by the led-out line for M3 among a plurality of sequences of triangular plotted points) and one spurious mode M1 of the resonator R1 (indicated by the led-out line for M1 among a plurality of sequences of circular plotted points). This region could not be confirmed in FIG. 4. Thus, it was confirmed that by changing the frequencies using not only the pitch p but also the duty, it is possible to create a spurious-free region in which no spurious occurs in the vicinities of the resonant frequencies. Specifically, when the thickness of the piezoelectric film 7 is set to 0.414 μm±0.01 μm, generation of spurious in the vicinities of the resonant frequencies can be suppressed.

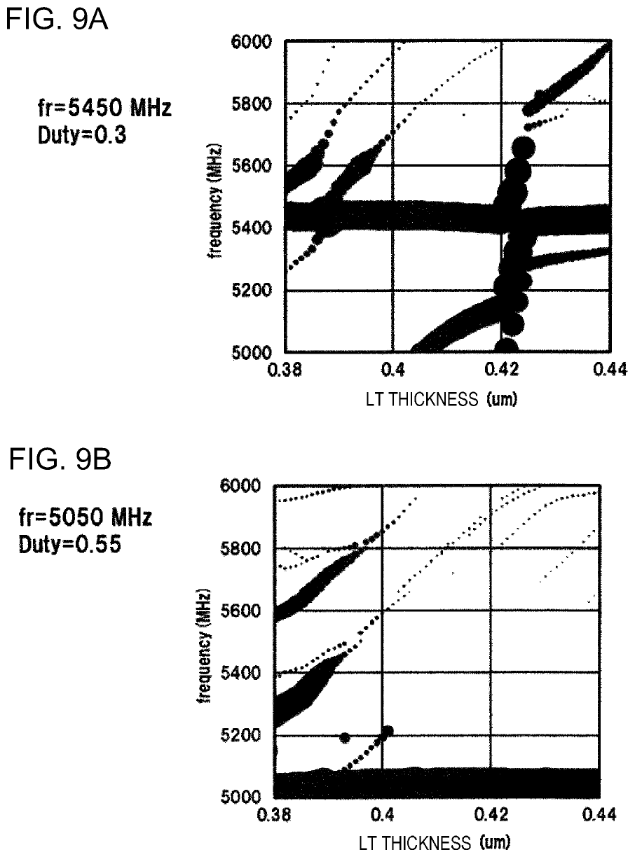

In addition, the intensity of spurious generated at higher frequencies than the resonant frequencies can also be reduced. FIGS. 9A and 9B illustrate the relationship between substrate thickness and the frequency of spurious generated in the resonator R1 and the resonator R3. The spurious intensity is represented by the size of the bubbles. It is clear from this figure that by setting the thickness of the substrate so as to lie within the above-described range, it is possible to reduce the spurious intensity at frequencies higher than the resonant frequencies and therefore at frequencies higher than the passband of the filter.

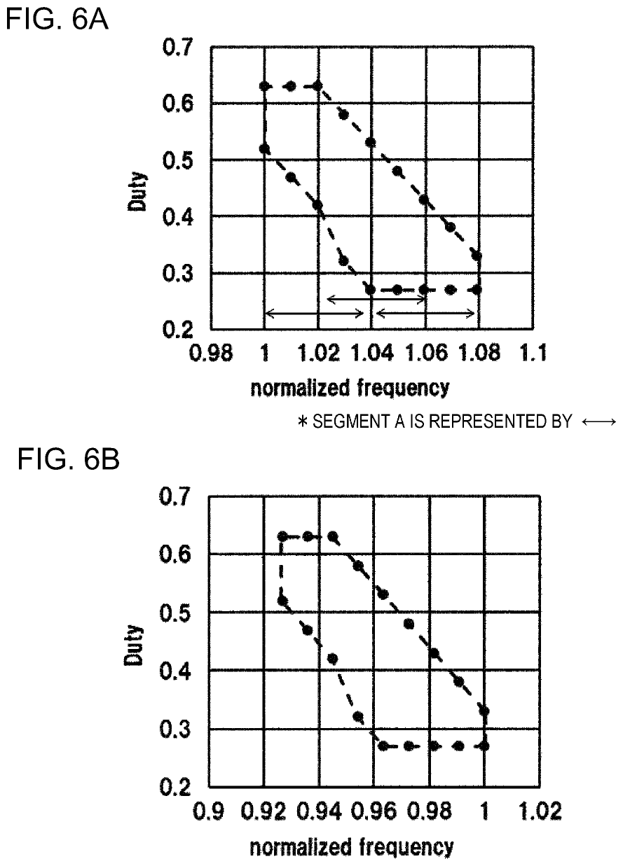

FIGS. 6A and 6B illustrate the relationship between resonant frequency and duty that realizes the spurious-free region interposed between the modes M1 and M3. For the purpose of generalization, FIGS. 6A and 6B illustrate the simulation of conditions under which the normalized frequencies of one particular resonator and at least one other resonator can be positioned in the spurious-free region when the resonant frequencies of the plurality of resonators used to form the filter have been normalized using the resonant frequency of the one particular resonator. In FIGS. 6A and 6B, the horizontal axis represents normalized frequency (no units) and the vertical axis represents duty (no units).

FIG. 6A is a chart illustrating the correlation between resonant frequency and duty for a resonator on the low frequency side and FIG. 6B is a chart illustrating the correlation between resonant frequency and duty for a resonator on the high frequency side.

FIGS. 6A and 6B were specifically obtained as follows.

For the simulation conditions, the resonant frequency was set to various values in a range from 5050 MHz to 5450 MHz and the duty was set to various values in a range from 0.2 to 0.7. In addition, the pitch p was set so that the set resonant frequency was realized with the set duty. In other words, a plurality of resonators having different resonant frequencies and duties (and pitches p) were considered. The rest of the conditions of the plurality of resonators were the same as those described above.

The frequencies at which the spurious of the modes M1 and M3 occurred were obtained by simulation for each of the plurality of resonators set up as described above. From another viewpoint, for each resonator, characteristics plotted as in FIG. 5 were calculated. Then, for each resonator, it was determined whether a spurious-free region in which spurious of the mode M1 and the mode M3 are not located was secured. Specifically, it was basically determined whether or not the frequencies at which the modes M1 and M3 (and other modes) occurred were located in a range of thickness tLT from 0.40 to 0.42 and a range of frequency from 5050 MHz to 5450 MHz, and if they were not located, it was determined that a spurious-free region was secured.

For each resonant frequency, the upper limit of duty where the spurious-free region is secured and the lower limit of duty where the spurious-free region is secured were determined. In FIGS. 6A and 6B, the determined upper and lower limits of duty are illustrated using dashed lines. The horizontal axis in FIG. 6A is normalized using 5050 MHz, which is the lower limit of the above-described frequency range. The horizontal axis in FIG. 6B is normalized using 5450 MHz, which is the upper limit of the above-described frequency range.

When designing the IDT electrodes 9 of two or more resonators, a combination of duty and resonant frequency may be determined so that the coordinates are located within a closed space enclosed by a dashed line in FIG. 6A and/or FIG. 6B. Then, the pitch p may be adjusted so that the desired resonant frequency can be realized for the specified duty. Since plate waves are used in this case, the resonant frequency fr is, for example, 4 GHz or higher.

In the case where the acoustic wave device 1 includes a ladder filter, for example, when the resonant frequency of the parallel resonator having the lowest resonant frequency among the plurality of parallel resonators P is used as a reference, the relationship between duty and resonant frequency for at least two or more of the plurality of series resonators S and the plurality of parallel resonators P may lie within the range indicated by the dashed line in FIG. 6A. In addition or alternatively, when the resonant frequency of the series resonator having the highest resonant frequency among the plurality of series resonators S is used as a reference, the relationship between duty and resonant frequency for at least two or more of the plurality of series resonators S and the plurality of parallel resonators P may lie within the range indicated by the dashed line in FIG. 6B.

If the frequency difference (difference in resonant frequency) segment to be realized is smaller than the entire width in the normalized frequency direction of the closed space illustrated in FIG. 6A and/or FIG. 6B, the starting point of the segment can be freely chosen within the range of the closed space. In other words, in FIG. 6A, as indicated by the double-headed arrows, for example, when a segment A corresponding to 4% in terms of the normalized frequency is to be realized, a normalized frequency range of 1.0 to 1.04 may be used or a range starting from a normalized frequency of 1.04 may be used as the segment A.

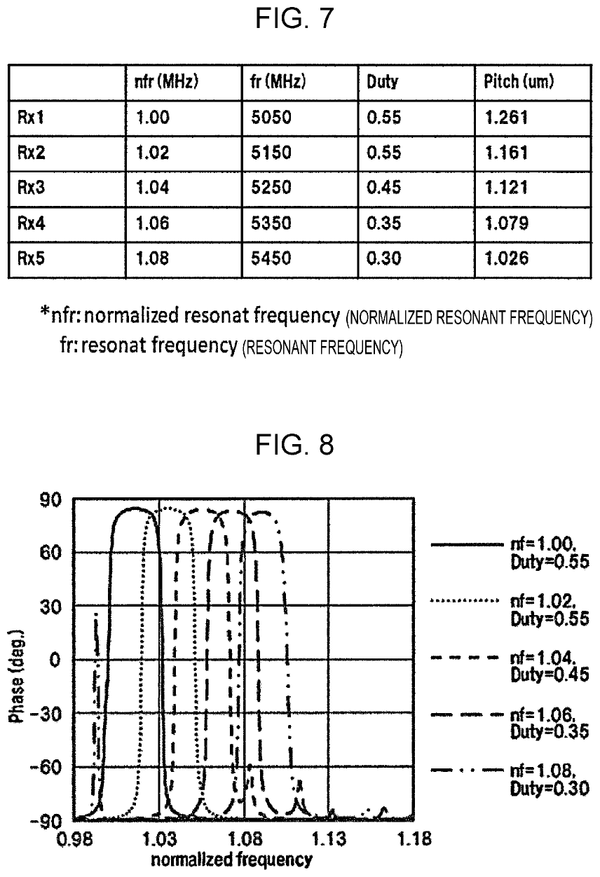

The conditions adopted when manufacturing resonators Rx1 to Rx5 with combinations of normalized frequency and duty located inside the dashed line in FIG. 6A are illustrated in FIG. 7 and the frequency characteristics of the resonators are illustrated in FIG. 8. Conditions of the resonators other than the design values listed in FIG. 7 are as follows.

Support Substrate 3: Si Substrate

Multilayer Film 5: 8 Layers

First Layers: Material SiO₂, Thickness 0.2 μm

Second Layers: Material HfO₂, Thickness 0.17 μm

Piezoelectric Film 7: Material 114° Y Rotation X Propagation LT Substrate, Thickness 0.406 μm

IDT Electrode 9: Material Al, Thickness 0.13 μm

Protective Film on IDT Electrode 9: Material SiO₂, Thickness 0.013 μm

As is clear also from FIG. 8, for each resonator, spurious as illustrated in FIG. 3 was not confirmed in the vicinities of the resonant frequencies and anti-resonant frequencies of the other resonators. In particular, when forming a ladder filter, the pass band of the ladder filter is formed by substantially aligning the anti-resonant frequencies of the parallel resonators and the resonant frequencies of the series resonators. Here, checking the combination of resonators in which the anti-resonant frequency of a resonator on the low-frequency side and the resonant frequency of a resonator on the high-frequency side overlap in FIG. 8, it can be confirmed that there is no spurious in the vicinity of the pass band.

Furthermore, according to the characteristics of the resonators illustrated in FIG. 8, it is clear that no significant spurious can be confirmed even on the high-frequency side of the anti-resonant frequency, and therefore it is clear that the effect on other filters and so on located on the high-frequency side can also be reduced.

As described above, according to the acoustic wave device 1 according to the embodiment, by using plate waves, a plurality of resonators having high resonant frequencies exceeding 5 GHz can be positioned on the piezoelectric film 7 having a uniform thickness, and frequency characteristics with reduced spurious can be realized.

In addition, the acoustic wave device 1 having reduced loss can be provided by adjusting the resonant frequencies by varying both the pitch p and duty. The reason for this is that, for example, as already described above, the effect of duty on the acoustic velocity of acoustic wave propagating in the piezoelectric film is small and the optimum design is easily realized for each of the two resonators. In addition, for example, the effect of the multilayer film 5 can also be given as a reason as described below.

The film thicknesses of the first layer 11 and the second layer 13 of the multilayer film 5 are determined so as to increase the reflectivity based on the pitch p. Here, as described above, the difference between the pitch p1 and the pitch p2 is larger than in a typical acoustic wave device in order to form the pass band of the filter. Therefore, if the thickness of each layer of the multilayer film 5 is set to the optimum value for one resonator, it will be significantly shifted from the optimal configuration for the other resonator. When the desired frequency difference is realized by only adjusting the pitch p, the difference between the absolute values of the pitches p of the two resonators is increased, and therefore loss is increased in the other resonator. In contrast, according to the acoustic wave device 1, since the difference between the pitches p in the two resonators can be made smaller, the shift from the optimum film thickness configuration of the multilayer film can be reduced, and as a result, loss can be reduced.

In the above-described example, series and parallel resonators forming a ladder filter are described as examples of resonators having different resonant frequencies, but other types of resonators may be used. For example, two or more filters having different pass bands may be disposed on a piezoelectric film having a uniform thickness, and the technology according to the present disclosure may be applied to the resonators forming one filter and the resonators forming the other filter. In addition, the technology according to the present disclosure may be applied to resonators forming one filter and to resonators used for adjustment of characteristics connected to the resonators forming the filter.

### Another Embodiment

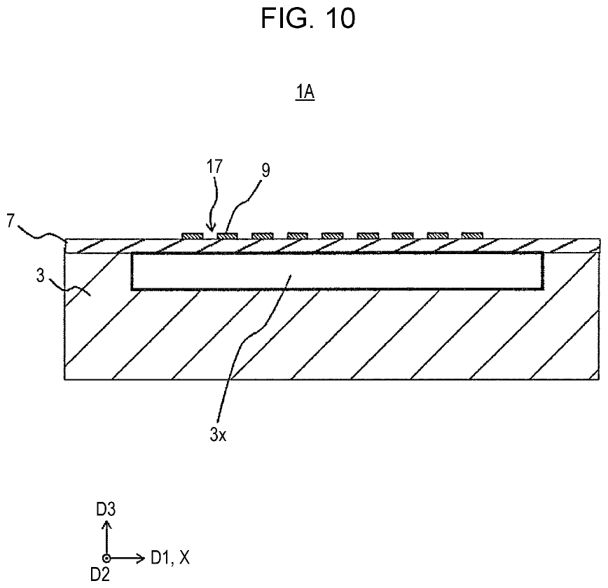

In the above-described example, a configuration provided with the multilayer film 5 and the support substrate 3 is described as an example, but the multilayer film 5 and the support substrate 3 are not necessarily provided. FIG. 10 illustrates a schematic sectional view of an acoustic wave device 1A according to another embodiment of the present disclosure.

In the acoustic wave device 1A, the piezoelectric film 7 is directly disposed on the support substrate 3 and a recess 3x is formed in the support substrate 3 at the position of the part of the piezoelectric film 7 that overlaps the position of the IDT electrode 9. In other words, the piezoelectric film 7 has the form of a “membrane” supported by the support substrate 3 with a space therebetween.

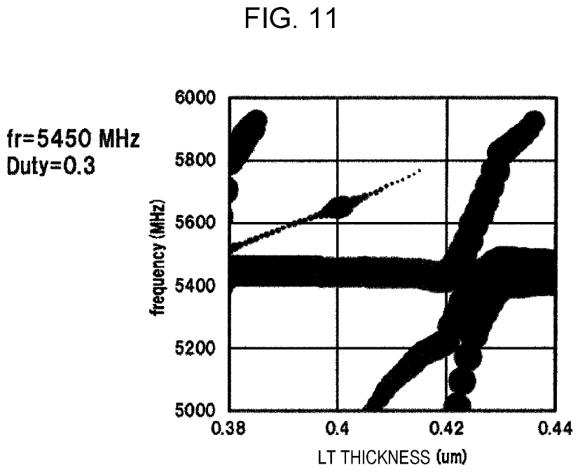

FIG. 11 is a diagram illustrating the relationship between piezoelectric film thickness and frequency of spurious for the resonator in FIG. 9A, when the multilayer film is not provided, the shape of the support substrate 3 is the shape illustrated in FIG. 10, and the rest of the design is the same. The spurious intensity is represented by the size of the bubbles. As is clear from the figure, there is almost no difference in the spurious intensity and frequency between the case where the multilayer film is provided and the case where the multilayer film is not provided (membrane).

According to the results, a multilayer film is a useful structure for confining plate waves, but is not essential for reducing the type of spurious considered here (from another viewpoint, multilayer films have little effect on the spurious considered here).

From the above description, it is clear that the results obtained for the acoustic wave device 1 (for example, FIGS. 5 to 9) mainly depend on the design of the piezoelectric film and the electrode fingers, and have little dependence on the presence or absence of a multilayer film, the material or thickness of a multilayer film, the presence or absence of a support substrate, or the material or thickness of a support substrate.

### Another Embodiment

In the above-described example, a case in which LT having a cut angle of 114° is used as the piezoelectric film 7 is described as an example but another cut angle may be used and another material may be used.

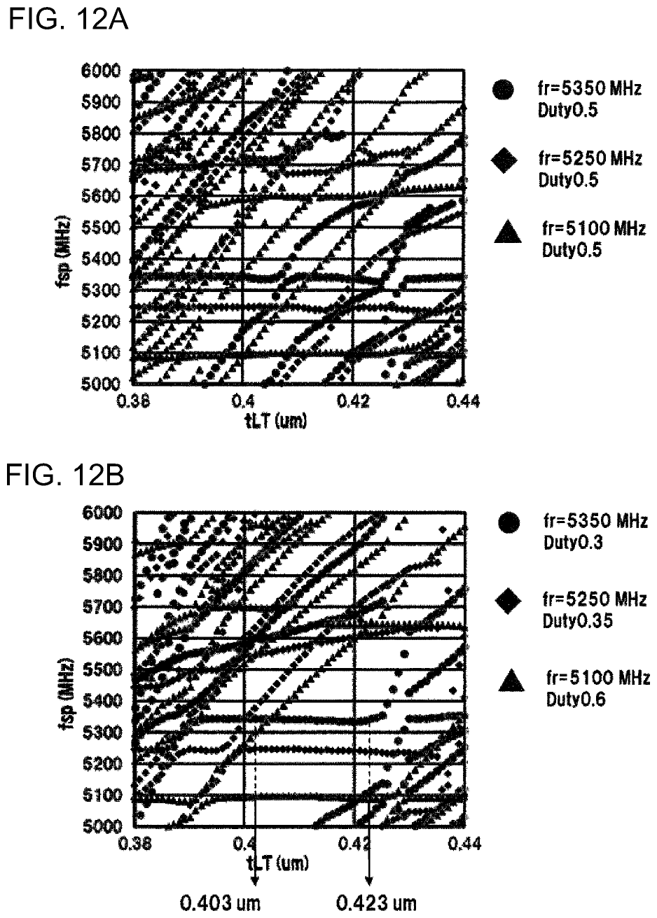

FIG. 12A illustrates a diagram corresponding to FIG. 4 and FIG. 12B illustrates a diagram corresponding to FIG. 5 for a case where a 106° Y rotation X propagation LT substrate is used as the piezoelectric film 7. From these figures, it was confirmed that a spurious-free region appears as a result of the duty being adjusted even when the cut angle is different.

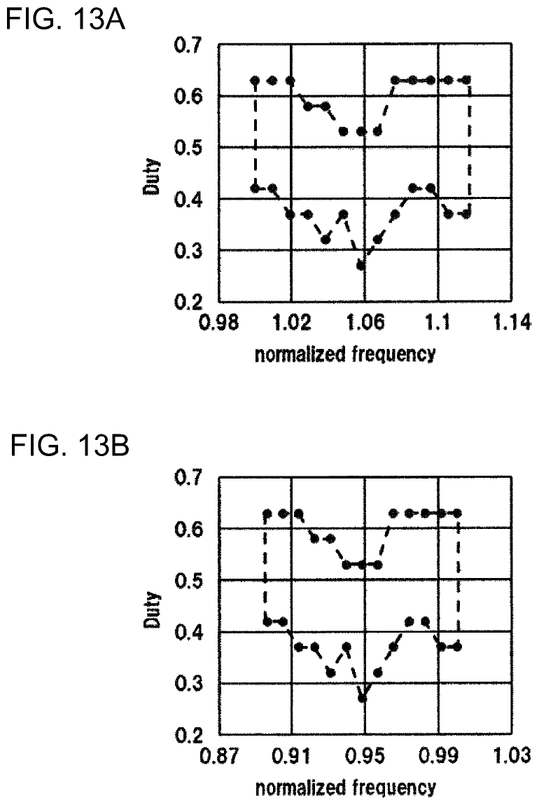

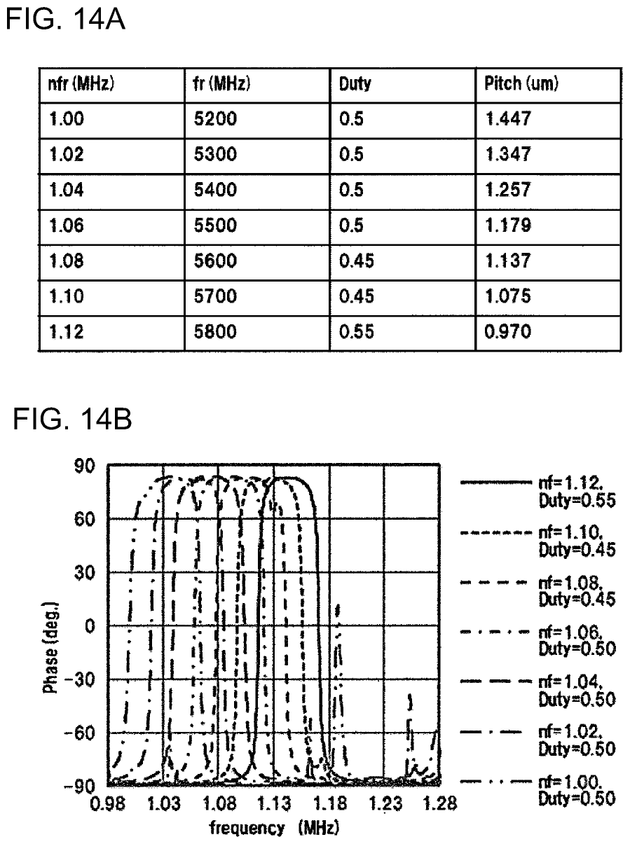

In addition, figures corresponding to FIGS. 6A and 6B are illustrated in FIGS. 13A and 13B and figures corresponding to FIGS. 7 and 8 are illustrated in FIGS. 14A and 14B, respectively, for a case where a 105° Y rotation X propagation LN substrate (Euler angles (0°, 15°, 0°) is used as the piezoelectric film. From these figures, it could be confirmed that spurious can be reduced by adjusting duty in the same manner even when an LN substrate is used.

In the simulations detailed in FIG. 13A to FIG. 14B, conditions other than the design values listed in FIG. 14A are as follows.

Support Substrate 3: Si Substrate

Multilayer Film 5: 8 Layers

First Layers: Material SiO₂, Thickness 0.2 μm

Second Layers: Material Ta₂O₅, Thickness 0.14 μm

Piezoelectric Film 7: Thickness 0.386 μm

IDT Electrode 9: Material Al, Thickness 0.11 μm

Protective Film on IDT Electrode 9: Material SiO₂, Thickness 0.013 μm

In addition, for this configuration, the same results as in FIGS. 13A to 14B were obtained when the multilayer film 5 had the following configuration.

Multilayer Film 5: 8 Layers

First Layers: Material SiO₂, Thickness 0.2 μm

Second Layers: Material Ta₂O₅, Thickness 0.16 μm

### Another Embodiment

In FIGS. 6A and 6B, a resonant frequency width was confirmed that could be adjusted while maintaining a spurious-free region with the duty kept constant. As a result, it was confirmed that the adjustable resonant frequency width could be made maximally large when the duty is from 0.29 to 0.31. Thus, in an acoustic wave device using plate waves, if the duties of the IDT electrodes are set to lie in a range from 0.29 to 0.31, which is smaller than is usually the case, spurious is easily reduced in each of a plurality of resonators having different resonant frequencies. In addition, spurious is easily reduced in an acoustic wave device including a plurality of resonators. In this case as well, the support substrate and the multilayer film may be omitted and the piezoelectric film may have a so-called membrane shape.

### Another Embodiment

The thickness of the piezoelectric film may be greater than or equal to 0.3p taking into consideration the workability and so forth of the piezoelectric film. In this case, since it is possible to realize a thickness having less deviation from the desired film thickness, as a result, better electrical characteristics can be realized. In addition, the thickness of the piezoelectric film may be less than or equal to 0.6p taking into account the effect of spurious, and therefore the thickness of the piezoelectric film may be from 0.3p to 0.6p.

In the description of the embodiments, examples have been used in which both pitch and duty are made different in the two resonators. However, the duty alone may be made different in the two resonators. For example, within a single filter, the resonant frequencies of a plurality of series resonators may slightly shifted in order to finely adjust the characteristics of the filter. In this case, the pitch may be the same but the duties may be different in the plurality of series resonators. The same applies to a plurality of parallel resonators.

### REFERENCE SIGNS LIST

1 . . . acoustic wave device

3 . . . support substrate

5 . . . multilayer film

7 . . . piezoelectric film

9 . . . IDT electrode

1. An acoustic wave device that uses a plate wave, the acoustic wave device comprising:
a piezoelectric film; and
a first resonator and a second resonator each including an IDT electrode located on an upper surface of the piezoelectric film,
wherein a thickness of the piezoelectric film is smaller than twice a period of electrode fingers of the IDT electrode of each of the first resonator and the second resonator, and
a duty of the electrode fingers of the first resonator and a duty of the electrode fingers of the second resonator are different from each other.

2. The acoustic wave device according to claim 1,
wherein the first resonator has a resonant frequency that is higher than a resonant frequency of the second resonator,
the period of the electrode fingers of the first resonator is smaller than the period of the electrode fingers of the second resonator, and
the duty of the electrode fingers of the first resonator is smaller than the duty of the electrode fingers of the second resonator.

3. The acoustic wave device according to claim 1,
wherein the first resonator has a resonant frequency that is higher than a resonant frequency of the second resonator, and
a ratio obtained by dividing the period of the electrode fingers of the second resonator by the period of the electrode fingers of the first resonator is larger than a ratio obtained by dividing the resonant frequency of the first resonator by the resonant frequency of the second resonator.

4. The acoustic wave device according to claim 1, further comprising:
a support substrate; and
a multilayer film located on the support substrate,
wherein the piezoelectric film is located on the multilayer film.

5. The acoustic wave device according to claim 2,
wherein a filter is formed in which a plurality of series resonators and a plurality of parallel resonators are connected to each other in a ladder configuration,
at least one of the plurality of series resonators is the first resonator, and
at least one of the plurality of parallel resonators is the second resonator.

6. The acoustic wave device according to claim 5,
wherein a relationship between duty and resonant frequency of at least two or more of the plurality of series resonators and the plurality of parallel resonators lies within a range indicated by a dashed line in FIG. 6A when the resonant frequency of a parallel resonator having a lowest resonant frequency among the plurality of parallel resonators is used as a reference,
or,
a relationship between duty and resonant frequency of at least two or more of the plurality of series resonators and the plurality of parallel resonators lies within a range indicated by a dashed line in FIG. 6B when the resonant frequency of a series resonator having a highest resonant frequency among the plurality of series resonators is used as a reference.

7. The acoustic wave device according to claim 1, further comprising:
a first layer and a second layer that are stacked in an alternating manner below the piezoelectric film,
wherein the first layer is composed of SiO₂ and has film thickness of 0.20 μm±0.01 μm,
the second layer is composed of HfO₂ and has film thickness of 0.17 μm±0.01 μm, and
the piezoelectric film is composed of 114° Y rotation X propagation lithium tantalate single crystal.

8. An acoustic wave device comprising:
a piezoelectric film composed of 106° Y rotation X propagation lithium tantalate single crystal, 114° Y rotation X propagation lithium tantalate single crystal, or 105° Y rotation X propagation lithium niobate single crystal; and
a first resonator and a second resonator each including an IDT electrode located on an upper surface of the piezoelectric film,
wherein a thickness of the piezoelectric film is smaller than twice a period of electrode fingers of the IDT electrode of each of the first resonator and the second resonator, and
a duty of the electrode fingers of the first resonator and a duty of the electrode fingers of the second resonator are different from each other.

9. An acoustic wave device that uses a plate wave, the acoustic wave device comprising:
a support substrate;
a multilayer film located on the support substrate;
a piezoelectric film located on the multilayer film; and
a first resonator and a second resonator each including an IDT electrode located on an upper surface of the piezoelectric film,
wherein a thickness of the piezoelectric film is smaller than a period of electrode fingers of the IDT electrode of each of the first resonator and the second resonator,
the multilayer film includes a first layer and a second layer having a higher acoustic impedance than the first layer, and
a duty of the first resonator and a duty of the second resonator lie in a range from 0.29 to 0.31.
